(19) United States
(12) Patent Application Publication
(10) Pub. No.: US 2003/0197628 A1
(43) Pub. Date: Oct. 23, 2003

(54) Collapsible keyboard

(75) Inventor: Chien-Shih Hsu, Taipei (TW)

Correspondence Address: Quintero Law Office, 3rd Floor, 1617 Broadway, Santa Monica, CA, 90404, US

(73) Assignee: Darfon Electronics Corp.

(21) Appl. No.: 10/410,987

(22) Filed: Apr. 10, 2003

(30) Foreign Application Priority Data
Apr. 17, 2002 (TW) 91205125

(51) Int. Cl. H03M 11/00; H03K 17/94

(52) U.S. Cl. 341/22

(57) ABSTRACT

A collapsible keyboard. The collapsible keyboard includes a supporting frame, a first sliding mount, a first keyboard group, a second keyboard group, and a first link. The first sliding mount is rotatably connected to the supporting frame. The first keyboard group is disposed on the supporting frame. The first link comprises a first end, pivoting on the first sliding mount, and a second end, pivoting on the second keyboard group such that the second keyboard group either slides above the first keyboard group or is disposed on the same level with respect to the first keyboard group.

### BACKGROUND OF THE INVENTION

1. Field of the Invention

The present invention relates in general to a collapsible keyboard, facilitating transport.

2. Description of the Related Art

Generally, characters and symbols are input into a computer via a keyboard. Other input equipment such as mouse pointers or light pens fail to offer input speed and ease to match the keyboard. Therefore, the popularity of keyboards remains universal.

A conventional keyboard has a keyboard base, a key base and a plurality of keys. The key base is mounted on the keyboard base, while the keys are mounted on the key base. The user inputs data into the computer by typing the keys of the keyboard. Operation of the computer using the keyboard is easy and fast. Conventional keyboards are, however, too long to allow easy transport.

Japan patent No. 8-190834 provides a collapsible keyboard, facilitating transport. The keyboard has three sections. Each section of the keyboard is linked to the others by tenons. Attachment by tenons can fail with repeated use. Thus, the keyboard is unstable and structurally weak.

### SUMMARY OF THE INVENTION

The present invention is directed to a collapsible keyboard, facilitating transport.

The keyboard of the present invention includes a supporting frame, a first sliding mount, a first keyboard group, a second keyboard group, and a first link. The first sliding mount is rotatably connected to the supporting frame. The first keyboard group is disposed on the supporting frame. The first link comprises a first end, pivoting on the first sliding mount, and a second end, pivoting on the second keyboard group such that the second keyboard group either slides above the first keyboard group or is disposed on the same level with respect to the first keyboard group.

The keyboard in use has a longitudinal size equal to that of a conventional keyboard to comply with user habits. When the keyboard is not in use, the user can collapse the keyboard such that the keyboard is easily transported.

### DESCRIPTION OF THE DRAWINGS

For a better understanding of the present invention, reference is made to a detailed description to be read in conjunction with the accompanying drawings, in which:

FIG. 1 is a perspective exploded diagram of a collapsible keyboard in accordance with the present invention;

FIGS. 2A and 2B depict the sliding mounts of the collapsible keyboard in accordance with the present invention in a collapsing operation;

FIG. 3A depicts the keyboard groups and sliding mounts of the collapsible keyboard in accordance with the present invention in a collapsed position.

FIG. 3B depicts the keyboard groups and sliding mounts of the collapsible keyboard in accordance with the present invention in a collapsing operation;

FIG. 3C depicts the keyboard groups and sliding mounts of the collapsible keyboard in accordance with the present invention, extended into functional position;

FIG. 4A is a front view of the collapsible keyboard in accordance with the present invention in a collapsed position.

FIG. 4B is a front view showing the operation of the keyboard groups and the sliding mounts of the collapsible keyboard in accordance with the present invention; and

FIG. 4C is a front view showing the operation of the keyboard groups and the sliding mounts of the collapsible keyboard in accordance with the present invention, extended into functional position.

### DETAILED DESCRIPTION OF THE INVENTION

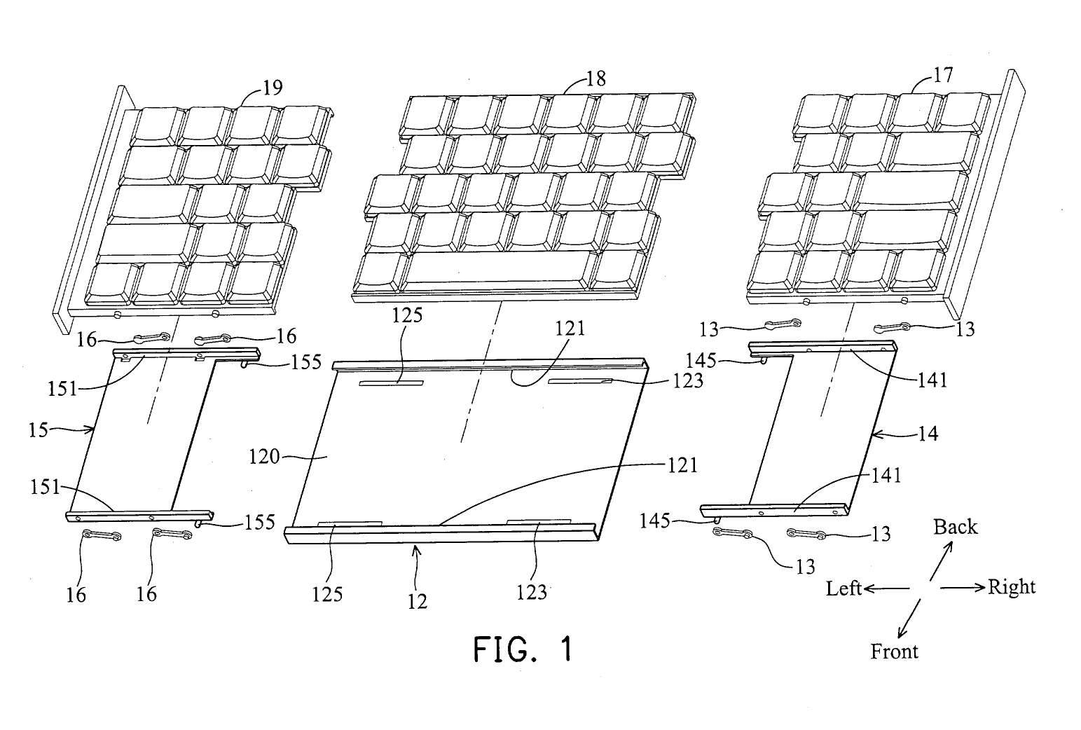

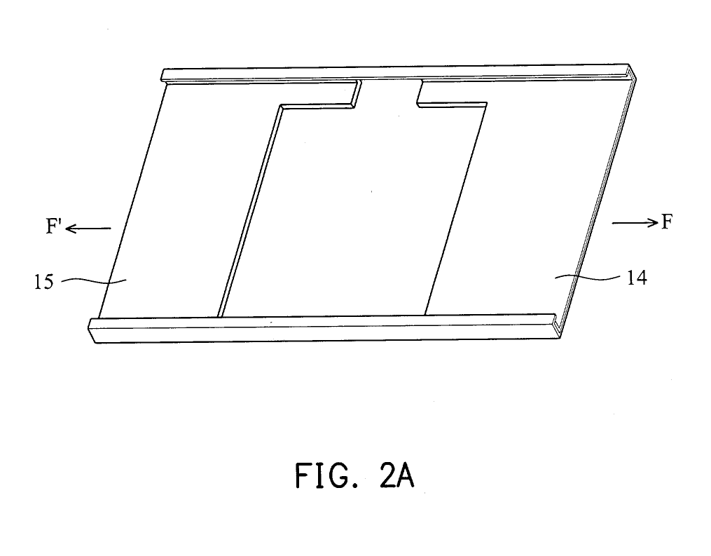

FIG. 1 is a perspective exploded diagram of a collapsible keyboard in accordance with the present invention. In FIG. 1, symbols such as front, back, left and right are shown for the following detailed description. The keyboard is constructed of a supporting frame 12, sliding mounts 14, 15, links 13, 16, and keyboard groups 17, 18, 19. The supporting frame 12 has a rectangular frame body 120. The front and back edges of the rectangular frame body 120 form a groove 121 to constrain the edges 141, 151 of the sliding mounts 14, 15 such that the edges 141, 151 slide along the groove 121. Moreover, parallel grooves 123, 125 are provided near the front and back edges of the rectangular frame body 120 to contain the sliding mounts 14, 15, and the protrusions 145, 155 thereof slide along the groove. FIGS. 2A and 2B depict the sliding mounts 14, 15 of the collapsible keyboard in accordance with the present invention in a collapsing operation. When the sliding mounts 14, 15 receive external force F, F′ from each side, respectively, the sliding mounts 14, 15 on the supporting frame 12 easily slide outward with respect to the supporting frame 12. The grooves 123, 125 of the supporting frame 12 restrict the moveable range of the protrusions 145, 155 of the sliding mounts 14, 15 and further prevent the separation of the sliding mount 14, 15 and the supporting frame 12.

In FIG. 1 again, one end of the link 13 pivots on the right keyboard group 17, and the other end pivots on the sliding mount 14. The link 13, right keyboard group 17, and the sliding mount 14 are formed as a four-bar mechanism. Similarly, the left keyboard group 19 is connected to the sliding mount 15 by the link 16 to form another four-bar mechanism.

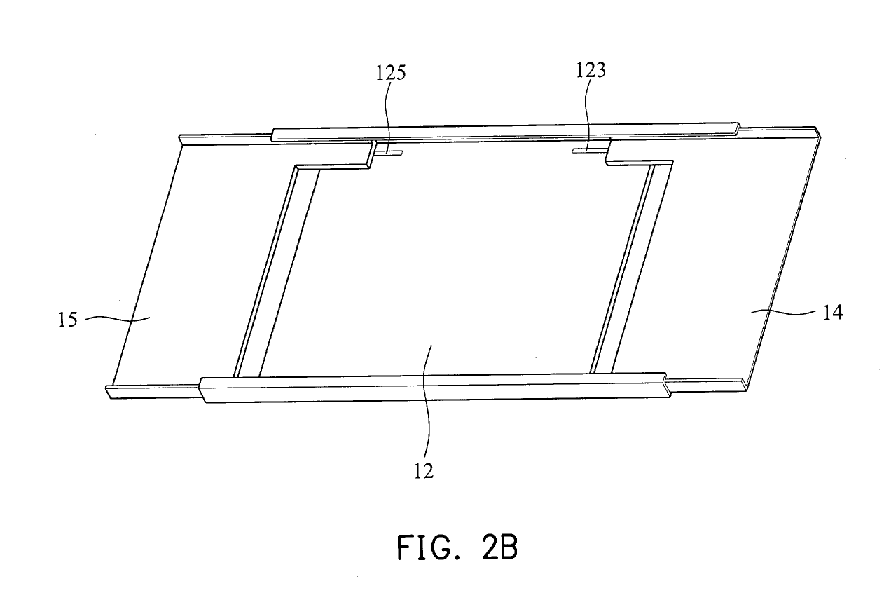

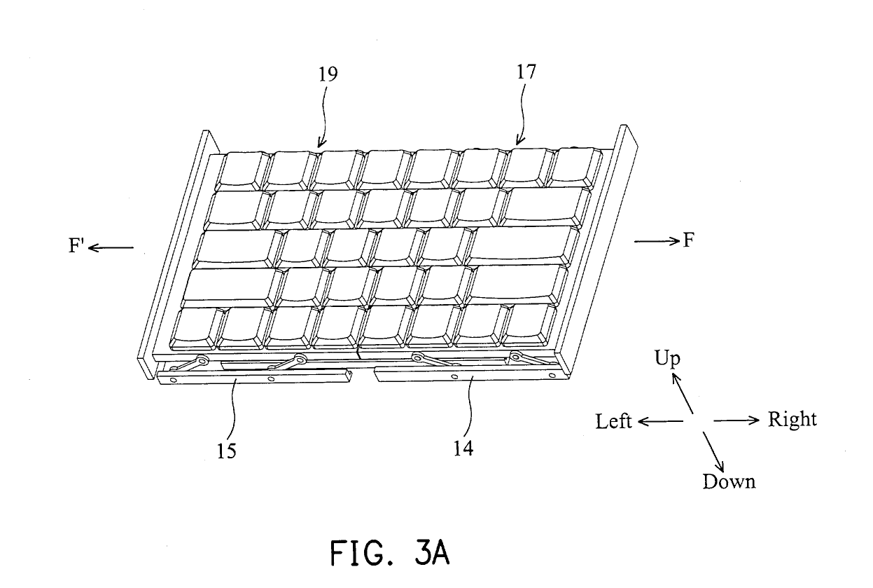

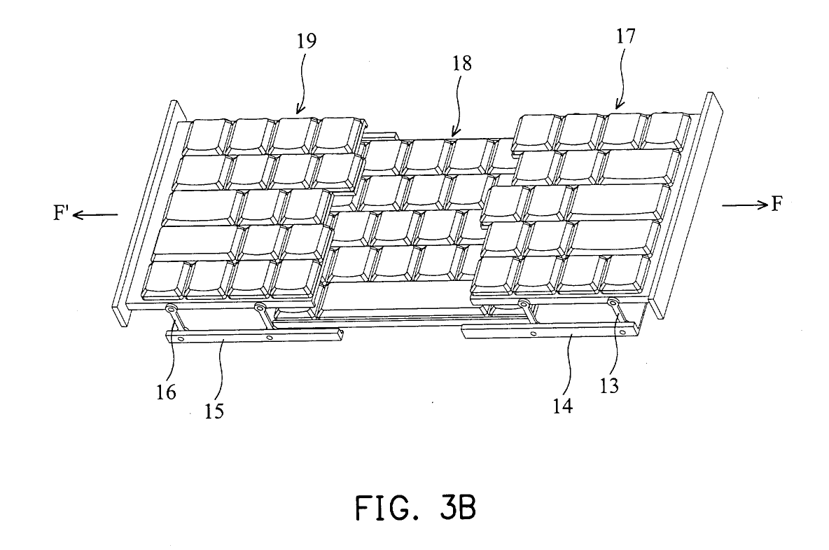

FIGS. 3A, 3B, and 3C depict the keyboard groups 17, 18, 19 and sliding mounts 14, 15 of the collapsible keyboard in accordance with the present invention. Symbols up, down, left, and right are shown in FIG. 3A for the following description. The supporting frame 12 is not shown here to avoid blocking the views of the sliding mounts 14, 15. However, the sliding mounts 14, 15 still slide on the supporting frame 12 (as shown in FIGS. 2A and 2B) . When the keyboard is collapsed, the middle keyboard group 18 is disposed directly above the supporting frame, and the left, right keyboard groups 19, 17 are disposed on the middle keyboard group 18. When the user applies forces F, F′ to pull the left, right keyboard groups 19, 17 respectively (as shown in FIG. 3A), the left, right keyboard groups 19, 17 respectively move left and right to reveal the lower layer of the middle keyboard group 18 (as shown in FIG. 3B). Meanwhile, the links 16, 13 drive the sliding mounts 15, 14 left and right, respectively. The motion of the left and right keyboard groups 19, 17 is as follows: moving up first, then down, and finally to the same level as the middle keyboard group 18 (as shown in FIG. 3C).

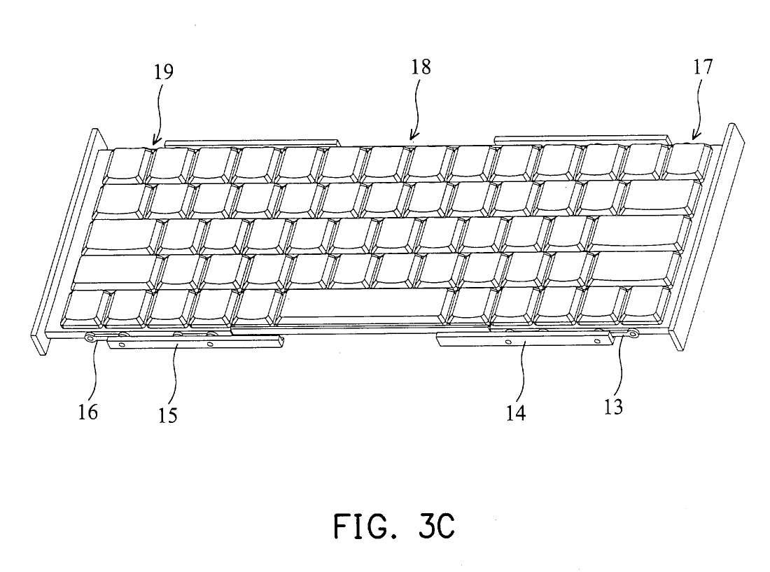

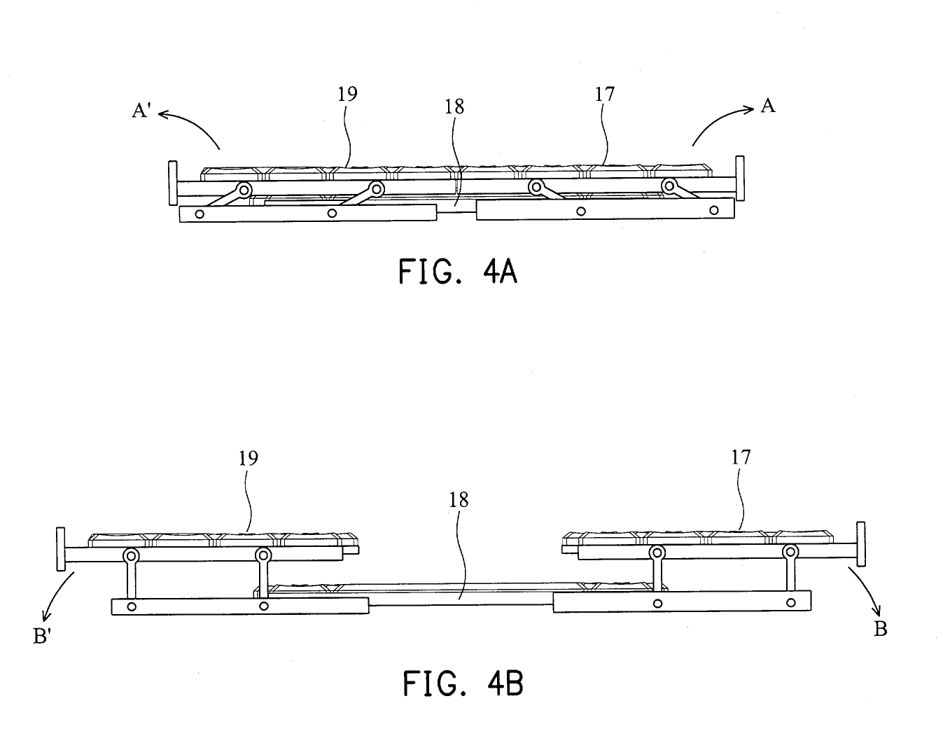

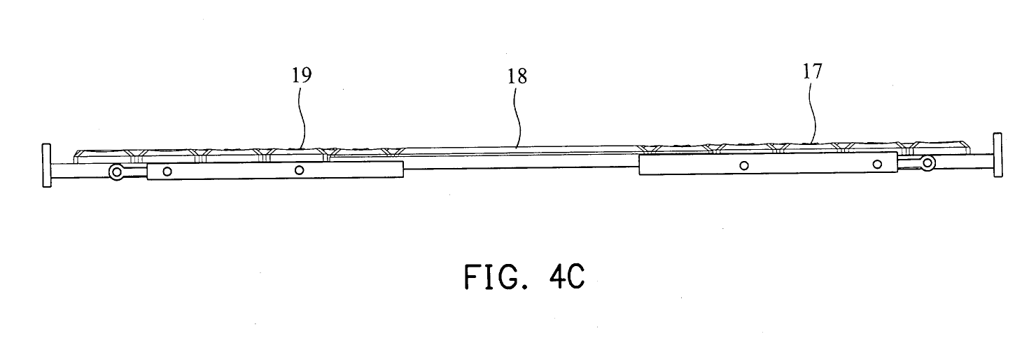

FIGS. 4A, 4B, and 4C are viewed from the front to observe the motion of the keyboard groups 17, 18, 19 and the sliding mounts 14, 15. As shown in the figures, the left and right keyboard groups 19, 17 move up along the direction A′, A. Next, 19 and 17 move down along the direction B′, B. Finally, 19 and 17 are disposed on the same level as the middle keyboard group 18.

In conclusion, the present invention provides a collapsible keyboard. The keyboard in use has a longitudinal size equal to that of a conventional keyboard to comply with user habits. When the keyboard is not in use, the user can collapse the keyboard such that the keyboard is easily carried.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A collapsible keyboard, comprising:
a supporting frame;
a first sliding mount, movably connected to the supporting frame;
a first keyboard group, disposed on the supporting frame;
a second keyboard group; and
a first link, comprising a first end, pivoting on the first sliding mount, and a second end, pivoting on the second keyboard group such that the second keyboard group either overlies the first keyboard group or is arranged on the same level with respect to the first keyboard group.

2. A collapsible keyboard as claimed in claim 1, wherein the supporting frame has a groove, and the first sliding mount has a protrusion to constrain the first sliding mount in the groove of the supporting frame such that they are firmly connected to each other.

3. A collapsible keyboard as claimed in claim 1, wherein the supporting frame has a groove, and the first sliding mount has edges sliding along the groove.

4. A collapsible keyboard as claimed in claim 1, further comprising a second sliding mount, movably connected to the supporting frame, a third keyboard group, and a second link, wherein the second link comprises a third end pivoting on the second sliding mount, and a fourth end pivoting on the third keyboard group such that the third keyboard group either overlies the first keyboard group or is arranged on the same level with respect to the first keyboard group.

5. A collapsible keyboard as claimed in claim 4, wherein the supporting frame has a groove, and the second sliding mount has a protrusion to constrain the second sliding mount in the groove of the supporting frame such that they are firmly connected to each other.

6. A collapsible keyboard as claimed in claim 4, wherein the supporting frame has a groove, and the first sliding mount has edges sliding along the groove.

7. A collapsible keyboard, comprising:
a supporting frame;
a first keyboard group, disposed on the supporting frame; and
a first four-bar mechanism, including a first sliding mount, movably connected to the supporting frame, a second keyboard group and two first links, connecting the first sliding mount to the second keyboard such that the second keyboard either overlies the first keyboard group or is arranged on the same level with respect to the first keyboard group.

8. A collapsible keyboard as claimed in claim 7, further comprising a second four-bar mechanism, comprising a second sliding mount movably connected to the supporting frame, a third keyboard group and two second links connecting the second sliding mount to the third keyboard group such that the third keyboard either overlies the first keyboard group or is arranged on the same level with respect to the first keyboard group.

9. A collapsible keyboard, comprising:
a supporting frame;
a first sliding mount, movably connected to the supporting frame;
a first key board group, comprising a first lower and a first upper surface, wherein the first lower surface is disposed on the supporting frame;
a second keyboard group, comprising a second lower and a second upper surface; and
a first link, comprising a first end pivoting on the first sliding mount and a second end pivoting on the second keyboard group such that the second keyboard group is disposed on the first sliding mount and is movable between a first position and a second position,
wherein when the second keyboard is located in the first position, the second lower surface of the second keyboard group overlies the first upper surface of the first keyboard group; and when the second keyboard is located in the second position, the second upper surface of the second keyboard is arranged at the same level as the first upper surface of the first keyboard group.

10. A collapsible keyboard as claimed in claim 9, wherein the supporting frame has a groove on each side thereof, and the edge of the first sliding mount is disposed therein and slides along the groove.

11. A collapsible keyboard as claimed in claim 9, further comprising a second sliding mount, movably connected to the supporting frame, a third keyboard group having a third lower and upper surface, and a second link, comprising a third end pivoting on the second sliding mount, and a fourth end pivoting on the third keyboard group such that the third keyboard group is disposed on the second sliding mount and movable between a third position and a fourth position; wherein, when the third keyboard group is located in the third position, the third lower surface of the third keyboard group overlies the first upper surface of the first keyboard group; and when the third keyboard is located at the fourth position, the third upper surface of the third keyboard is arranged on the same level as the first upper surface of the first keyboard group.

12. A collapsible keyboard as claimed in claim 11, wherein the both first and second sliding mounts comprise protrusions, respectively, and the supporting frame is provided with a groove corresponding to each protrusion, disposed and constrained in the groove to further constrain the first and the second sliding mounts within the supporting frame without separating.

13. A collapsible keyboard as claimed in claim 9, wherein the supporting frame comprises a groove, and the second sliding mount has edges sliding in the groove.
